(19) United States
(12) Patent Application Publication
(10) Pub. No.: US 2022/0384422 A1
(43) Pub. Date: Dec. 1, 2022

(54) SEMICONDUCTOR DEVICE

(71) Applicant: KABUSHIKI KAISHA TOSHIBA, Tokyo (JP)

(72) Inventor: Akira MUKAI, Kawasaki (JP)

(73) Assignee: KABUSHIKI KAISHA TOSHIBA, Tokyo (JP)

(21) Appl. No.: 17/527,531

(22) Filed: Nov. 16, 2021

(30) Foreign Application Priority Data
Jun. 1, 2021 (JP) 2021-092088

(51) Int. Cl. H01L 27/06; H01L 29/20; H01L 29/205; H01L 29/872; H01L 29/778

(52) U.S. Cl. CPC H01L 27/0605; H01L 29/2003; H01L 29/205; H01L 29/872; H01L 29/7786

(57) ABSTRACT

According to one embodiment, a semiconductor device includes first to fifth electrodes, a semiconductor member, a first insulating member, and first and second connecting members. The third electrode includes a first electrode portion. The first electrode portion is between the first electrode and the second electrode. The fifth electrode includes a first electrode region. The semiconductor member includes first and second semiconductor regions. The first semiconductor region includes first to seventh partial regions. The fourth partial region is between the first and third partial regions. The fifth partial region is between the third and second partial regions. The second semiconductor region includes first, second, and third semiconductor portions. The first insulating member includes a first insulating region. The first connecting member electrically connects the fifth electrode with the first electrode. The second connecting member electrically connects the fourth electrode with the third electrode.

### CROSS-REFERENCE TO RELATED APPLICATIONS

This application is based upon and claims the benefit of priority from Japanese Patent Application No. 2021-092088, filed on Jun. 1, 2021; the entire contents of which are incorporated herein by reference.

### FIELD

Embodiments described herein generally relate to a semiconductor device.

### BACKGROUND

For example, in a semiconductor device such as a transistor, stable characteristics are desired.

### BRIEF DESCRIPTION OF THE DRAWINGS

FIG. 1 is a schematic cross-sectional view illustrating a semiconductor device according to a first embodiment;

FIG. 2 is a circuit diagram illustrating the semiconductor device according to the first embodiment; and

FIG. 3 is a graph illustrating characteristics of the semiconductor device according to the first embodiment.

### DETAILED DESCRIPTION

According to one embodiment, a semiconductor device includes a first electrode, a second electrode, a third electrode, a fourth electrode, a fifth electrode, a semiconductor member, a first insulating member, a first connecting member, and a second connecting member. A direction from the first electrode to the second electrode is along a first direction. The third electrode includes a first electrode portion. A position of the first electrode portion in the first direction is between a position of the first electrode in the first direction and a position of the second electrode in the first direction. The fifth electrode includes a first electrode region. The semiconductor member includes a first semiconductor region and a second semiconductor region. The first semiconductor region includes Alₓ₁Ga₁₋ₓ₁N (0≤x1<1). The first semiconductor region includes a first partial region, a second partial region, a third partial region, a fourth partial region, a fifth partial region, a sixth partial region, and a seventh partial region. A direction from the first partial region to the first electrode, a direction from the second partial region to the second electrode, and a direction from the third partial region to the first electrode portion are along a second direction crossing the first direction. A position of the fourth partial region in the first direction is between a position of the first partial region in the first direction and a position of the third partial region in the first direction. A position of the fifth partial region in the first direction is between the position of the third partial region in the first direction and a position of the second partial region in the first direction. A direction from the second partial region to the sixth partial region crosses the second direction. A direction from the sixth partial region to the fourth electrode is along the second direction. A direction from the sixth partial region to the seventh partial region is along a first crossing direction crossing the second direction. The second semiconductor region includes Alₓ₂Ga₁₋ₓ₂N (0<x2≤1, x1<x2). The second semiconductor region includes a first semiconductor portion, a second semiconductor portion, and a third semiconductor portion. A direction from the fourth partial region to the first semiconductor portion is along the second direction. A direction from the fifth partial region to the second semiconductor portion is along the second direction. A direction from the seventh partial region to the third semiconductor portion is along the second direction. The third semiconductor portion is in contact with at least a part of the first electrode region. The first insulating member includes a first insulating region. The first insulating region is between the third partial region and the first electrode portion in the second direction. At least a part of the first insulating region is between the fourth partial region and the fifth partial region in the first direction. The first connecting member electrically connects the fifth electrode with the first electrode. The second connecting member electrically connects the fourth electrode with the third electrode.

According to one embodiment, a semiconductor device includes a first electrode, a second electrode, a third electrode, a fourth electrode, a fifth electrode, a semiconductor member, and a first insulating member. A direction from the first electrode to the second electrode is along a first direction. The third electrode includes a first electrode portion. A position of the first electrode portion in the first direction is between a position of the first electrode in the first direction and a position of the second electrode in the first direction. The fifth electrode includes a first electrode region. The semiconductor member includes a first semiconductor region and a second semiconductor region. The first semiconductor region includes Alₓ₁Ga₁₋ₓ₁N (0≤x1<1). The first semiconductor region includes a first partial region, a second partial region, a third partial region, a fourth partial region, a fifth partial region, a sixth partial region, and a seventh partial region. A direction from the first partial region to the first electrode, a direction from the second partial region to the second electrode, and a direction from the third partial region to the first electrode portion are along a second direction crossing the first direction. A position of the fourth partial region in the first direction is between a position of the first partial region in the first direction and a position of the third partial region in the first direction. A position of the fifth partial region in the first direction is between the position of the third partial region in the first direction and a position of the second partial region in the first direction. A direction from the second partial region to the sixth partial region crosses the second direction. A direction from the sixth partial region to the fourth electrode is along the second direction. A direction from the sixth partial region to the seventh partial region is along a first crossing direction crossing the second direction. The second semiconductor region includes Alₓ₂Ga₁₋ₓ₂N (0<x2≤1, x1<x2). The second semiconductor region includes a first semiconductor portion, a second semiconductor portion, and a third semiconductor portion. A direction from the fourth partial region to the first semiconductor portion is along the second direction. A direction from the fifth partial region to the second semiconductor portion is along the second direction. A direction from the seventh partial region to the third semiconductor portion is along the second direction. The third semiconductor portion is in contact with at least a part of the first electrode region. The first insulating member includes a first insulating region. The first insulating region is between the third partial region and the first electrode portion in the second direction. At least a part of the first insulating region is between the fourth partial region and the fifth partial region in the first direction. The fifth electrode is electrically connected with the first electrode, or the fifth electrode is configured to be electrically connected with the first electrode. The fourth electrode is electrically connected with the third electrode, or the fourth electrode is configured to be electrically connected with the third electrode.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

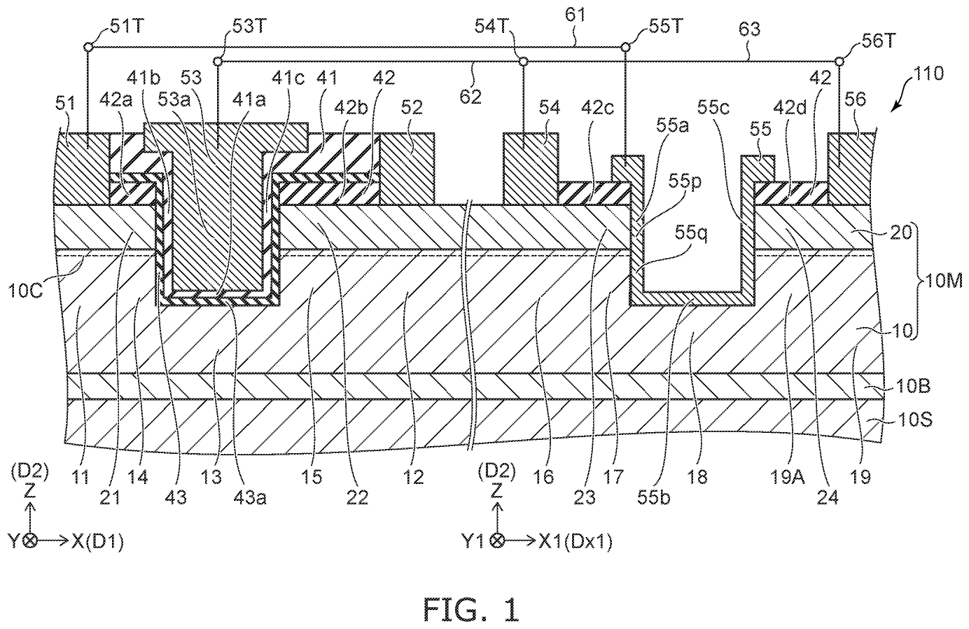

FIG. 1 is a schematic cross-sectional view illustrating a semiconductor device according to a first embodiment.

As shown in FIG. 1, the semiconductor device 110 according to the embodiment includes a first electrode 51, a second electrode 52, a third electrode 53, a fourth electrode 54, a fifth electrode 55, a semiconductor member 10M, and a first insulation. Includes member 41.

A direction from the first electrode 51 to the second electrode 52 is along a first direction D1. The first direction D1 is an X-axis direction. One direction perpendicular to the X-axis direction is defined as a Z-axis direction. A direction perpendicular to the X-axis direction and the Z-axis direction is defined as a Y-axis direction.

The third electrode 53 includes a first electrode portion 53a. A position of the first electrode portion 53a in the first direction D1 is between a position of the first electrode 51 in the first direction D1 and a position of the second electrode 52 in the first direction D1. For example, in the first direction D1, at least a part of the third electrode 53 may be provided between the first electrode 51 and the second electrode 52.

The fifth electrode 55 includes a first electrode region 55a.

The semiconductor member 10M includes a first semiconductor region 10 and a second semiconductor region 20. In this example, the semiconductor device 110 includes a base body 10S and a nitride semiconductor layer 10B. The nitride semiconductor layer 10B is provided on the base body 10S. The first semiconductor region 10 is provided on the nitride semiconductor layer 10B. The second semiconductor region 20 is provided on the first semiconductor region 10. The base body 10S may be, for example, a silicon substrate or a SiC substrate. The nitride semiconductor layer 10B includes, for example, a nitride semiconductor. The nitride semiconductor layer 10B includes, for example, Al, Ga, N and the like. The nitride semiconductor layer 10B is, for example, a buffer layer.

The first semiconductor region 10 includes Alₓ₁Ga₁₋ₓ₁N (0≤x1<1). The composition ratio x1 is, for example, not less than 0 and not more than 0.1. In one example, the first semiconductor region 10 is a GaN layer.

The first semiconductor region 10 includes a first partial region 11, a second partial region 12, a third partial region 13, a fourth partial region 14, a fifth partial region 15, a sixth partial region 16, and a seventh partial region 17. A direction from the first partial region 11 to the first electrode 51, a direction from the second partial region 12 to the second electrode 52, and a direction from the third partial region 13 to the first electrode portion 53a (at least a part of the third electrode 53) are along a second direction D2. The second direction D2 crosses the first direction D1. The second direction D2 is, for example, the Z-axis direction.

A position of the fourth partial region 14 in the first direction D1 is between a position of the first partial region 11 in the first direction D1 and a position of the third partial region 13 in the first direction D1. A position of the fifth partial region 15 in the first direction D1 is between the position of the third partial region 13 in the first direction D1 and the position of the second partial region 12 in the first direction D1.

A direction from the second partial region 12 to the sixth partial region 16 crosses the second direction D2. The direction from the second partial region 12 to the sixth partial region 16 may be any direction along the X-Y plane.

A direction from the sixth partial region 16 to the fourth electrode 54 is along the second direction D2. The direction from the sixth partial region 16 to the seventh partial region 17 is along a first crossing direction Dx1. The first crossing direction Dx1 crosses the second direction D2. The first crossing direction Dx1 may be along the first direction D1. In the example of FIG. 1, the first crossing direction Dx1 is along an X1-axis direction. The X1-axis direction is perpendicular to the Z-axis direction. A Y1-axis direction is perpendicular to the X1-axis direction and the Z-axis direction.

In the first to seventh partial regions 11 to 17, the boundaries between them may be unclear. A region in the first semiconductor region 10 that overlaps the first electrode 51 in the second direction D2 corresponds to the first partial region 11. A region in the first semiconductor region 10 that overlaps the second electrode 52 in the second direction D2 corresponds to the second partial region 12. A region in the first semiconductor region 10 overlaps the third electrode 53 in the second direction D2 corresponds to the third partial region 13. A region in the first semiconductor region 10 that overlaps the fourth electrode 54 in the second direction D2 corresponds to the sixth partial region 16.

The second semiconductor region 20 includes Alₓ₂Ga₁₋ₓ₂N (0<x2<1, x1<x2). The composition ratio x2 is not less than 0.15 and not more than 0.3. The second semiconductor region 20 is, for example, an AlGaN layer.

The second semiconductor region 20 includes a first semiconductor portion 21, a second semiconductor portion 22, and a third semiconductor portion 23. A direction from the fourth partial region 14 to the first semiconductor portion 21 is along the second direction D2. A direction from the fifth partial region 15 to the second semiconductor portion 22 is along the second direction D2. A direction from the seventh partial region 17 to the third semiconductor portion 23 is along the second direction D2. The third semiconductor portion 23 is in contact with at least a part (part 55p) of the first electrode region 55a.

The first insulating member 41 includes a first insulating region 41a. The first insulating region 41a is between the third partial region 13 and the first electrode portion 53a in the second direction D2. At least a part of the first insulating region 41a is between the fourth partial region 14 and the fifth partial region 15 in the first direction D1.

The fifth electrode 55 is electrically connected with the first electrode 51. Alternatively, the fifth electrode 55 is configured to be electrically connected with the first electrode 51.

The fourth electrode 54 is electrically connected with the third electrode 53. Alternatively, the fourth electrode 54 is configured to be electrically connected with the third electrode 53.

In this example, the semiconductor device 110 includes a first connecting member 61 and a second connecting member 62. The first connecting member 61 electrically connects the fifth electrode 55 with the first electrode 51. The second connecting member 62 electrically connects the fourth electrode 54 with the third electrode 53. The first connecting member 61 and the second connecting member 62 may be included in the semiconductor device 110. The first connecting member 61 and the second connecting member 62 may be provided separately from the semiconductor device 110. In this case, for example, at least one of a terminal 51T electrically connected with the first electrode 51, a terminal 53T electrically connected with the third electrode 53, a terminal 54T electrically connected with the fourth electrode 54, and a terminals 55T electrically connected with the fifth electrode 55 may be provided. These terminals are electrically connected by a connecting member.

A current flowing between the first electrode 51 and the second electrode 52 can be controlled by a potential of the third electrode 53. The potential of the third electrode 53 is, for example, a potential based on the potential of the first electrode 51. The first electrode 51 functions as, for example, a source electrode. The second electrode 52 functions as, for example, a drain electrode. The third electrode 53 functions as, for example, a gate electrode. A portion of the semiconductor device 110 including the first to third electrodes 51 to 53 functions as a transistor.

A carrier region 10C is formed in a portion of the first semiconductor region 10 facing the second semiconductor region 20. The carrier region 10C is, for example, a two-dimensional electron gas. The portion including the first to third electrodes 51 to 53 is, for example, HEMT (High Electron Mobility Transistor).

For example, a distance between the first electrode 51 and the third electrode 53 is shorter than a distance between the third electrode 53 and the second electrode 52. The first electrode 51 is electrically connected with, for example, the first semiconductor portion 21. The first electrode 51 may be electrically connected with, for example, the first partial region 11. The second electrode 52 is electrically connected with, for example, the second semiconductor portion 22. The second electrode 52 may be electrically connected with, for example, the second partial region 12.

In the embodiment, a portion including the fourth electrode 54 and the fifth electrode 55 functions as, for example, a two-terminal nonlinear element.

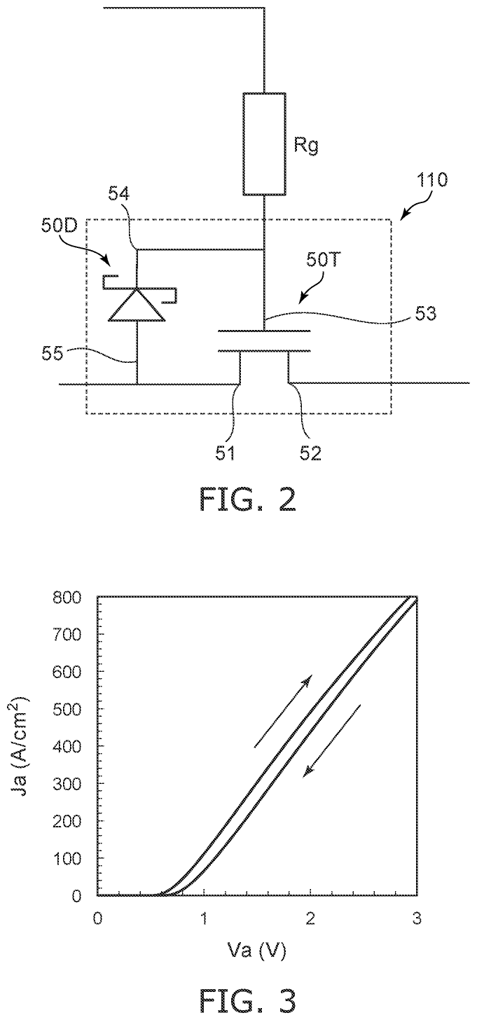

FIG. 2 is a circuit diagram illustrating the semiconductor device according to the first embodiment.

As shown in FIG. 2, a transistor 50T including a first electrode 51, a second electrode 52, and a third electrode 53 is provided. A diode 50D including a fourth electrode 54 and a fifth electrode 55 is provided. The fourth electrode 54 functions as a cathode of the diode 50D. The fifth electrode 55 functions as an anode of the diode 50D. The cathode of the diode 50D is electrically connected with the gate of the transistor 50T. The anode of the diode 50D is electrically connected with the source of the transistor 50T. For example, the gate is electrically connected with an external circuit (such as a control circuit) via a resistor Rg.

For example, in the transistor 50T, a negative bias may be applied to the gate electrode. As a result, a threshold voltage may fluctuate. For example, nBTI (Negative Bias Temperature Instability) occurs.

In the embodiment, the source of the transistor 50T is electrically connected with the anode of the diode 50D. The gate of the transistor 50T is electrically connected with the cathode of the diode 50D. As a result, the fluctuation of the threshold voltage due to the application of the negative bias is suppressed. According to the embodiment, it is possible to provide a semiconductor device capable of stabilizing the characteristics.

For example, a reference example in which a discrete diode is provided separately from the transistor can be considered. In this reference example, the parasitic inductance becomes large. Therefore, it is difficult to obtain a desired operation in high-speed switching.

In the embodiment, the transistor 50T and the diode 50D are provided in one semiconductor member 10M. Parasitic inductance can be suppressed. Stable operation can be obtained even with high-speed switching.

In the embodiment, for example, a material of the fifth electrode 55 is different from a material of the first electrode 51. A material of a portion of the fifth electrode 55 that is in contact with the semiconductor member 10M is different from a material of a portion of the first electrode 51 that is in contact with the semiconductor member 10M.

The fourth electrode 54, the fifth electrode 55, and the semiconductor member 10M function as a diode 50D. The diode 50D is, for example, a Schottky diode.

The fifth electrode 55 includes at least one selected from the group consisting of Ni, W, and TiN. These materials are capable of forming Schottky contacts with nitride semiconductors. For example, the fifth electrode 55 makes Schottky contact with the third semiconductor portion 23. For example, the fifth electrode 55 includes a film including at least one selected from the group consisting of Ni, W, and TiN, and this film may be in contact with the nitride semiconductor (eg, third semiconductor portion 23).

On the other hand, the fourth electrode 54 includes, for example, at least one selected from the group consisting of Ti and Al. These materials are capable of forming ohmic contact with nitride semiconductors. For example, the fourth electrode 54 makes ohmic contact with the third semiconductor portion 23 (for example, AlGaN). The fourth electrode 54 may make ohmic contact with the sixth partial region 16 (for example, GaN). For example, the fourth electrode 54 includes, for example, a film including at least one selected from the group consisting of Ti and Al, and this film may be in contact with a nitride semiconductor (for example, the third semiconductor portion 23).

In the embodiment, the seventh partial region 17 may be provided between the sixth partial region 16 and another part (part 55q) of the first electrode region 55a in the first crossing direction Dx1. For example, a part of the first electrode region 55a may be provided in the recess region provided in the semiconductor member 10M. Another portion (part 55q) of the first electrode region 55a may be in contact with the seventh partial region 17. For example, the fifth electrode 55 makes Schottky contact with the seventh partial region 17.

As shown in FIG. 1, the fifth electrode 55 may include a second electrode region 55b. The second electrode region 55b may be continuous with the first electrode region 55a. The first electrode region 55a is provided, for example, corresponding to a side surface of the recess provided in the semiconductor member 10M. The second electrode region 55b is provided, for example, corresponding to the bottom of the recess.

The first semiconductor region 10 may include an eighth partial region 18. A position of the seventh partial region 17 in the first crossing direction Dx1 is between a position of the sixth partial region 16 in the first crossing direction Dx1 and a position of the eighth partial region 18 in the first crossing direction Dx1. The eighth partial region 18 corresponds to a region of the first semiconductor region 10 that overlaps the fifth electrode 55 in the second direction D2.

A part of the seventh partial region 17 is between the sixth partial region 16 and the second electrode region 55b in the first crossing direction Dx1. For example, at least a part of the seventh partial region 17 is in contact with the second electrode region 55b. The second electrode region 55b may be in Schottky contact with the seventh partial region 17 and the eighth partial region 18.

As shown in FIG. 1, in this example, the semiconductor device 110 includes a sixth electrode 56. The sixth electrode 56 is electrically connected with the fourth electrode 54. The semiconductor device 110 may further include a third connecting member 63. For example, the first semiconductor region 10 may include a ninth partial region 19 and a tenth partial region 19A. The position of the eighth partial region 18 in the first crossing direction Dx1 is between a position of the seventh partial region 17 in the first crossing direction Dx1 and a position of the ninth partial region 19 in the first crossing direction Dx1. A position of the tenth partial region 19A in the first crossing direction Dx1 is between the position of the eighth partial region 18 in the first crossing direction Dx1 and the position of the ninth partial region 19 in the first crossing direction Dx1.

A direction from the ninth partial region 19 to the sixth electrode 56 is along the second direction D2 (Z-axis direction). The ninth partial region 19 corresponds to a region of the first semiconductor region 10 that overlaps the sixth electrode 56 in the second direction D2. The tenth partial region 19A is a region between the eighth partial region 18 and the ninth partial region 19 in the first crossing direction Dx1. Regarding the eighth partial region 18, the tenth partial region 19A and the ninth partial region 19, the boundaries between them may be unclear.

The second semiconductor region 20 includes a fourth semiconductor portion 24. A direction from the tenth partial region 19A to the fourth semiconductor portion 24 is along the second direction D2. The third connecting member 63 electrically connects the sixth electrode 56 with the fourth electrode 54.

For example, the sixth electrode 56 may be continuous with the fourth electrode 54 in a cross section different from the cross section illustrated in FIG. 1. For example, the sixth electrode 56 may be electrically connected with the fourth electrode 54 by another connecting member (third connecting member 63).

The sixth electrode 56 includes, for example, at least one selected from the group consisting of Ti and Al. For example, the sixth electrode 56 makes ohmic contact with the fourth semiconductor portion 24.

As shown in FIG. 1, the fifth electrode 55 may include a third electrode region 55c. For example, the third electrode region 55c is connected with the second electrode region 55b. For example, the second electrode region 55b is between the first electrode region 55a and the third electrode region 55c. The third electrode region 55c is in contact with, for example, a part of the fourth semiconductor portion 24 and the tenth partial region 19A. For example, the fifth electrode 55 may make Schottky contact with the fourth semiconductor portion 24.

As shown in FIG. 1, at least a part of the third electrode 53 is between the first semiconductor portion 21 and the second semiconductor portion 22 in the first direction D1. The first insulating member 41 includes a second insulating region 41b and a third insulating region 41c. The second insulating region 41b is between the first semiconductor portion 21 and at least a part of the third electrode 53 in the first direction D1. The third insulating region 41c is between at least a part of the third electrode 53 and the second semiconductor portion 22 in the first direction D1. The third electrode 53 is, for example, a recess type gate electrode. For example, a high threshold is obtained. For example, it is possible to operate in an enhanced mode.

In this example, the semiconductor device 110 includes a second insulating member 42. The second insulating member 42 includes, for example, a first insulating portion 42a and a second insulating portion 42b . The first semiconductor portion 21 is between the fourth partial region 14 and the first insulating portion 42a in the second direction D2. The second semiconductor portion 22 is between the fifth partial region 15 and the second insulating portion 42b in the second direction D2.

The first insulating member 41 includes at least one selected from the group consisting of silicon and aluminum, and oxygen. The first insulating member 41 includes, for example, at least one selected from the group consisting of silicon oxide and aluminum oxide. In one example, the first insulating member 41 is a silicon oxide layer.

The second insulating member 42 includes silicon and nitrogen. The second insulating member 42 includes, for example, silicon nitride.

The first insulating member 41 does not include nitrogen. Alternatively, a concentration of nitrogen in the first insulating member 41 is lower than a concentration of nitrogen in the second insulating member 42. The second insulating member 42 does not include oxygen. Alternatively, a concentration of oxygen in the second insulating member 42 is lower than a concentration of oxygen in the first insulating member 41.

By providing such a second insulating member 42, for example, the characteristics of the second semiconductor region 20 become more stable.

As shown in FIG. 1, the semiconductor device 110 may include a nitride member 43. The nitride member 43 includes Alₓ₃Ga₁₋ₓ₃N (0<x3≤1, x2<x3). The composition ratio x3 is, for example, not less than 0.8 and not more than 1. The nitride member 43 may be, for example, an AlN layer.

The nitride member 43 includes a first nitride region 43a. The first nitride region 43a is provided between the third partial region 13 and the first insulating region 41a in the second direction D2. By providing the nitride member 43, for example, the characteristics of the semiconductor member 10M become improved. By providing the nitride member 43, for example, it is easy to lower the on-resistance.

A part of the nitride member 43 may be provided between the semiconductor member 10M and the second insulating region 41b. A part of the nitride member 43 may be provided between the semiconductor member 10M and the third insulating region 41c. A part of the nitride member 43 may be provided between the first insulating portion 42a and the first insulating member 41. A part of the nitride member 43 may be provided between the second insulating portion 42b and the first insulating member 41.

FIG. 3 is a graph illustrating some characteristics of the semiconductor device according to the first embodiment.

FIG. 3 illustrates the measurement results of the characteristics of the diode 50D including the fourth electrode 54, the fifth electrode 55, and the semiconductor member 10M. The horizontal axis of FIG. 3 is the voltage Va applied between the fourth electrode 54 and the fifth electrode 55. The vertical axis is the current density Ja. As shown in FIG. 3, when the applied voltage Va is less than about 0.7 V, the current does not flow substantially. When the voltage Va becomes about 0.7 or more, the current density Ja increases as the voltage Va rises.

In the embodiment, a thickness of the first semiconductor portion 21 along the second direction D2 is thinner than a thickness of the fourth partial region 14 along the second direction D2. The carrier region 10C is stably formed. The thickness of the first semiconductor portion 21 along the second direction D2 is, for example, not less than 15 nm and not more than 40 nm. The thickness of the fourth partial region 14 along the second direction D2 is, for example, not less than 100 nm and not more than 1000 nm.

In the embodiment, a thickness of the nitride member 43 is, for example, not less than 1 nm and not more than 5 nm. A thickness of the second insulating member 42 is, for example, not less than 5 nm and not more than 20 nm. Information on the concentration of elements (or composition ratio) in the member can be obtained by, for example, SIMS (Secondary Ion Mass Spectrometry).

The third electrode 53 includes, for example, at least one selected from the group consisting of TiN, Ni, and W.

According to the embodiments, it is possible to provide a semiconductor device capable of stabilizing the characteristics.

In the specification, “nitride semiconductor” includes all compositions of semiconductors of the chemical formula BₓIn_{y}Al_{z}Ga_{1-x-y-z}N (0≤x≤1, 0≤y≤1, 0≤z≤1, and x+y+z≤1) for which the composition ratios x, y, and z are changed within the ranges respectively. “Nitride semiconductor” further includes group V elements other than N (nitrogen) in the chemical formula recited above, various elements added to control various properties such as the conductivity type and the like, and various elements included unintentionally.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices such as electrodes, semiconductor members, insulating members, connecting members, nitride members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode, a direction from the first electrode to the second electrode being along a first direction;
a third electrode including a first electrode portion, a position of the first electrode portion in the first direction being between a position of the first electrode in the first direction and a position of the second electrode in the first direction;
a fourth electrode;
a fifth electrode including a first electrode region;
a semiconductor member including a first semiconductor region and a second semiconductor region,
the first semiconductor region including Alₓ₁Ga₁₋ₓ₁N (0≤x1<1), the first semiconductor region including a first partial region, a second partial region, a third partial region, a fourth partial region, a fifth partial region, a sixth partial region, and a seventh partial region, a direction from the first partial region to the first electrode, a direction from the second partial region to the second electrode, and a direction from the third partial region to the first electrode portion being along a second direction crossing the first direction, a position of the fourth partial region in the first direction being between a position of the first partial region in the first direction and a position of the third partial region in the first direction, a position of the fifth partial region in the first direction being between the position of the third partial region in the first direction and a position of the second partial region in the first direction, a direction from the second partial region to the sixth partial region crossing the second direction, a direction from the sixth partial region to the fourth electrode being along the second direction, a direction from the sixth partial region to the seventh partial region being along a first crossing direction crossing the second direction;
the second semiconductor region including Alₓ₂Ga₁₋ₓ₂N (0<x2≤1, x1<x2), the second semiconductor region including a first semiconductor portion, a second semiconductor portion, and a third semiconductor portion, a direction from the fourth partial region to the first semiconductor portion being along the second direction, a direction from the fifth partial region to the second semiconductor portion being along the second direction, a direction from the seventh partial region to the third semiconductor portion being along the second direction, the third semiconductor portion being in contact with at least a part of the first electrode region;
a first insulating member including a first insulating region, the first insulating region being between the third partial region and the first electrode portion in the second direction, at least a part of the first insulating region being between the fourth partial region and the fifth partial region in the first direction;
a first connecting member electrically connecting the fifth electrode with the first electrode; and
a second connecting member electrically connecting the fourth electrode with the third electrode.

2. A semiconductor device, comprising:
a first electrode;
a second electrode, a direction from the first electrode to the second electrode being along a first direction;
a third electrode including a first electrode portion, a position of the first electrode portion in the first direction being between a position of the first electrode in the first direction and a position of the second electrode in the first direction;
a fourth electrode;
a fifth electrode including a first electrode region;
a semiconductor member including a first semiconductor region and a second semiconductor region,
the first semiconductor region including Alₓ₁Ga₁₋ₓ₁N (0≤x1<1), the first semiconductor region including a first partial region, a second partial region, a third partial region, a fourth partial region, a fifth partial region, a sixth partial region, and a seventh partial region, a direction from the first partial region to the first electrode, a direction from the second partial region to the second electrode, and a direction from the third partial region to the first electrode portion being along a second direction crossing the first direction, a position of the fourth partial region in the first direction being between a position of the first partial region in the first direction and a position of the third partial region in the first direction, a position of the fifth partial region in the first direction being between the position of the third partial region in the first direction and a position of the second partial region in the first direction, a direction from the second partial region to the sixth partial region crossing the second direction, a direction from the sixth partial region to the fourth electrode being along the second direction, a direction from the sixth partial region to the seventh partial region being along a first crossing direction crossing the second direction;
the second semiconductor region including Alₓ₂Ga₁₋ₓ₂N (0<x2≤1, x1<x2), the second semiconductor region including a first semiconductor portion, a second semiconductor portion, and a third semiconductor portion, a direction from the fourth partial region to the first semiconductor portion being along the second direction, a direction from the fifth partial region to the second semiconductor portion being along the second direction, a direction from the seventh partial region to the third semiconductor portion being along the second direction, the third semiconductor portion being in contact with at least a part of the first electrode region; and
a first insulating member including a first insulating region, the first insulating region being between the third partial region and the first electrode portion in the second direction, at least a part of the first insulating region being between the fourth partial region and the fifth partial region in the first direction,
the fifth electrode being electrically connected with the first electrode, or the fifth electrode being configured to be electrically connected with the first electrode, and
the fourth electrode being electrically connected with the third electrode, or the fourth electrode being configured to be electrically connected with the third electrode.

3. The device according to claim 1, wherein the fifth electrode includes at least one selected from the group consisting of Ni, W, and TiN.

4. The device according to claim 1, wherein the fifth electrode is in Schottky contact with the third semiconductor portion.

5. The device according to claim 1, wherein the seventh partial region is between the sixth partial region and an other part of the first electrode region in the first crossing direction.

6. The device according to claim 5, wherein the other part of the first electrode region is in contact with the seventh partial region.

7. The device according to claim 1, wherein the fifth electrode is in Schottky contact with the seventh partial region.

8. The device according to claim 1, wherein the fourth electrode, the fifth electrode, and the semiconductor member function as a diode.

9. The device according to claim 1, the fourth electrode includes at least one selected from the group consisting of Ti and Al.

10. The device according to claim 1, wherein the fourth electrode is in ohmic contact with the third semiconductor portion.

11. The device according to claim 1, wherein a distance between the first electrode and the third electrode is shorter than a distance between the third electrode and the second electrode.

12. The device according to claim 1, wherein
the fifth electrode includes a second electrode region,
the first semiconductor region includes an eighth partial region,
a position of the seventh partial region in the first crossing direction is between a position of the sixth partial region in the first crossing direction and a position of the eighth partial region in the first crossing direction,
a part of the seventh partial region is between the sixth partial region and the second electrode region in the first crossing direction, and
at least a part of the seventh partial region is in contact with the second electrode region.

13. The device according to claim 12, further comprising a sixth electrode electrically connected with the fourth electrode,
the first semiconductor region including a ninth partial region and a tenth partial region,
a position of the eighth partial region in the first crossing direction being between a position of the seventh partial region in the first crossing direction and a position of the ninth partial region in the first crossing direction,
a position of the tenth partial region in the first crossing direction being between the position of the eighth partial region in the first crossing direction and the position of the ninth partial region in the first crossing direction,
a direction from the ninth partial region to the sixth electrode being along the second direction
the second semiconductor region including a fourth semiconductor portion,
a direction from the tenth partial region to the fourth semiconductor portion is along the second direction.

14. The device according to claim 13, wherein
the fifth electrode includes a third electrode region connected with the second electrode region,
the third electrode region is in contact with the fourth semiconductor portion and a part of the tenth partial region.

15. The device according to claim 14, wherein the fifth electrode is in Schottky contact with the fourth semiconductor portion.

16. The device according to claim 1, wherein at least a part of the third electrode is between the first semiconductor portion and the second semiconductor portion in the first direction.

17. The device according to claim 16, wherein
the first insulating member includes a second insulating region and a third insulating region,
the second insulating region is between the first semiconductor portion and at least a part of the third electrode in the first direction, and
the third insulating region is between the at least the part of the third electrode and the second semiconductor portion in the first direction.

18. The device according to claim 1, further comprising a second insulating member,
the second insulating member including a first insulating portion and a second insulating portion,
the first semiconductor portion is between the fourth partial region and the first insulating portion in the second direction,
the second semiconductor portion is between the fifth partial region and the second insulating portion in the second direction,
the first insulating member including oxygen and at least one selected from the group consisting of silicon and aluminum,
the second insulating member including silicon and nitrogen
the first insulating member not including nitrogen, or a concentration of nitrogen in the first insulating member being lower than a concentration of nitrogen in the second insulating member, and
the second insulating member not including oxygen, or a concentration of oxygen in the second insulating member being lower than a concentration of oxygen in the first insulating member.

19. The device according to claim 1, further comprising a nitride member including Alₓ₃Ga₁₋ₓ₃N (0<x3≤1, x2<x3),
the nitride member including a first nitride region, and
the first nitride region being provided between the third partial region and the first insulating region in the second direction.

20. The device according to claim 1, wherein a thickness of the first semiconductor portion along the second direction is thinner than a thickness of the fourth partial region along the second direction.
